(19) United States
(12) Patent Application Publication
(10) Pub. No.: US 2020/0350000 A1
(43) Pub. Date: Nov. 5, 2020

(54) EFUSE MEMORY CELL AND EFUSE MEMORY, AND WRITE/READ METHODS THEREOF

(71) Applicants: Semiconductor Manufacturing International (Shanghai) Corporation, Shanghai (CN); Semiconductor Manufacturing International (Beijing) Corporation, Beijing (CN)

(72) Inventor: Chia Chi YANG, Shanghai (CN)

(21) Appl. No.: 16/864,490

(22) Filed: May 1, 2020

(30) Foreign Application Priority Data
May 5, 2019 (CN) 201910369120.1

(51) Int. Cl. G11C 11/4091; G11C 11/4094; G11C 11/408; G11C 11/4074; G11C 17/16

(52) U.S. Cl. CPC G11C 11/4091; G11C 11/4094; G11C 17/16; G11C 11/4074; G11C 11/4085

(57) ABSTRACT

The present disclosure provides an efuse memory cell, an efuse memory, and their write/read methods. The efuse memory cell has a write bit line terminal, a read bit line terminal, a read word line terminal, and a write word line terminal. The efuse memory cell further includes: an electric fuse, having a first terminal connecting to the write bit line terminal and a second terminal; a first control transistor, having a first terminal connecting to the second terminal of the electric fuse, a second terminal connecting to the read bit line terminal, and a control terminal connecting to the read word line terminal; and a second control transistor, having a first terminal connecting to the second terminal of the electric fuse, a second terminal which is a ground terminal, and a control terminal connecting to the write word line terminal.

### CROSS-REFERENCES TO RELATED APPLICATION

This application claims the priority of Chinese Patent Application No. 201910369120.1, filed on May 5, 2019, the content of which is incorporated herein by reference in its entirety.

### TECHNICAL FIELD

The present disclosure generally relates to the field of semiconductor technology and, more particularly, to an efuse memory cell, an efuse memory, and their write/read methods.

### BACKGROUND

In the field of semiconductor technology, efuse technology is widely used in many circuits as a one-time programmable memory, because it is compatible with Complementary Metal-Oxide-Semiconductor transistor (CMOS) logic devices and is easy to use.

The efuse technology uses a theory of electromigration to store information through whether an electric fuse is blown by a current. A polysilicon electric fuse has a small resistance before the electric fuse is blown, and the resistance can be regarded as infinite after the electric fuse is blown by a continuous high current. A status of the blown electric fuse will remain permanently. The efuse technology has been widely used in redundant circuits to improve chip failure and other problems, and can replace small-capacity one-time programmable memories.

A high current is required to program an efuse. Higher voltages (for example, 3.3 volts) and corresponding input and output devices are usually used to perform programming of an efuse. In a fin field effect process (fin fet process), at 28HK, below 14 nanometers, when a fuse becomes a metal fuse, a programming current of an efuse will become larger, which can reach 50 milliamps mA). Presence of NMOS increases an area of an efuse memory cell, makes the efuse memory cell larger, and limits promotion of the efuse memory cell.

Therefore, it is necessary to propose a new efuse memory cell and an efuse memory to solve the above technical problems.

### SUMMARY

One aspect of the present disclosure provides an efuse memory cell, including: a write bit line terminal; a read bit line terminal; a read word line terminal; a write word line terminal; an electric fuse, having a first terminal and a second terminal, that the first terminal of the electric fuse is connected to the write bit line terminal; a first control transistor, having a first terminal, a second terminal, and a control terminal, that the first terminal of the first control transistor is connected to the second terminal of the electric fuse, the second terminal of the first control transistor is connected to the read bit line terminal, and the control terminal of the first control transistor is connected to the read word line terminal; and a second control transistor, having a first terminal, a second terminal, and a control terminal, that the first terminal of the second control transistor is connected to the second terminal of the electric fuse, the second terminal of the second control transistor is a ground terminal, and the control terminal of the second control transistor is connected to the write word line terminal.

Another aspect of the present disclosure provides an efuse memory, including: a plurality of read word lines; a plurality of write word lines; a plurality of read bit lines; a plurality of write bit lines; a plurality of efuse memory cells, arranged in M rows and N columns, M and N are positive integers, that each of the plurality of efuse memory cells includes: a write bit line terminal; a read bit line terminal; a read word line terminal; a write word line terminal; an electric fuse, having a first terminal and a second terminal, such that the first terminal of the electric fuse is connected to the write bit line terminal; a first control transistor, having a first terminal, a second terminal, and a control terminal, such that the first terminal of the first control transistor is connected to the second terminal of the electric fuse, the second terminal of the first control transistor is connected to the read bit line terminal, and the control terminal of the first control transistor is connected to the read word line terminal; and a second control transistor, having a first terminal, a second terminal, and a control terminal, such that the first terminal of the second control transistor is connected to the second terminal of the electric fuse, the second terminal of the second control transistor is a ground terminal, and the control terminal of the second control transistor is connected to the write word line terminal; the read word line terminal of each of the plurality of efuse memory cells in a same row is connected to a same read word line, and the write word line terminal of each of the plurality of efuse memory cells in the same row is connected to a same write word line, such that the same read word line is one of the plurality of read word lines, and the same write word line is one of the plurality of write word lines; and the read bit line terminal of each of the plurality of efuse memory cells in a same column is connected to a same read bit line, and the write bit line terminal of each of the plurality of efuse memory cells in the same column is connected to a same write bit line, such that the same read bit line is one of the plurality of read bit lines, and the same write bit line is one of the plurality of write bit lines.

Another aspect of the present disclosure provides a write method, for writing the efuse memory according to embodiments of the present disclosure, including: controlling to turn on for a connection of a PMOS transistor connected to one of the plurality of efuse memory cells to be written; powering on one write bit line of the plurality of write bit lines connected to the one of the plurality of efuse memory cells to be written; and turning off for a disconnection of an NMOS transistor connected to the one of the plurality of efuse memory cells to be written; and controlling to turn off for a disconnection of the first control transistor of the one of the plurality of efuse memory cells to be written; and powering on one write word line of the plurality of write word lines connected to the one of the plurality of efuse memory cells to be written to blow the electric fuse of the one of the plurality of efuse memory cells to be written, to perform a write operation on the one of the plurality of efuse memory cells to be written.

Another aspect of the present disclosure provides a read method, for writing the efuse memory according to embodiments of the present disclosure, including: controlling to turn on for a connection of an NMOS transistor connected to one of the plurality of efuse memory cells to be read; powering on one read bit line of the plurality of read bit lines connected to the one of the plurality of efuse memory cells to be read; and turning off for a disconnection of a PMOS transistor connected to the one of the plurality of efuse memory cells to be read; and controlling to turn off for a disconnection of the second control transistor of the one of the plurality of efuse memory cells to be read; and powering on one read word line of the plurality of read word lines connected to the one of the plurality of efuse memory cells to be read, to perform a read operation on the one of the plurality of efuse memory cells to be read.

Other aspects or embodiments of the present disclosure can be understood by those skilled in the art in light of the description, the claims, and the drawings of the present disclosure.

### BRIEF DESCRIPTION OF THE DRAWINGS

The following drawings are merely examples for illustrative purposes according to various disclosed embodiments and are not intended to limit the scope of the present disclosure.

FIG. 1 is a schematic structural view of a conventional efuse memory cell;

FIG. 2 is a schematic structural view of a conventional efuse memory;

FIG. 3 is a schematic structural view of an efuse memory cell according to one embodiment of the present disclosure;

FIG. 4 is a schematic circuit diagram of performing read operations using one embodiment shown in FIG. 3; and

FIG. 5 is a schematic structural view of an efuse memory according to one embodiment of the present disclosure.

### DETAILED DESCRIPTION

A conventional efuse module requires a higher voltage and current o perform efuse programming, which increases an area of the conventional efuse, and is not conducive to promotion of the conventional efuse.

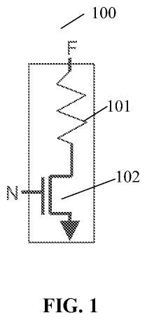

FIG. 1 is a schematic structural view of a conventional efuse memory cell. As shown in FIG. 1, an efuse memory cell 100 includes an electric fuse 101 and an NMOS transistor 102. Control of an efuse fusing current is mainly realized by the NMOS transistor 102 connected in series with the electric fuse 101.

Because a higher voltage is used to control the efuse fusing current, conventional solutions usually use a high threshold voltage transistor (High threshold voltage transistor, HVT for short). Because a volume of the HVT is larger than a core device, a size of an efuse memory is increased.

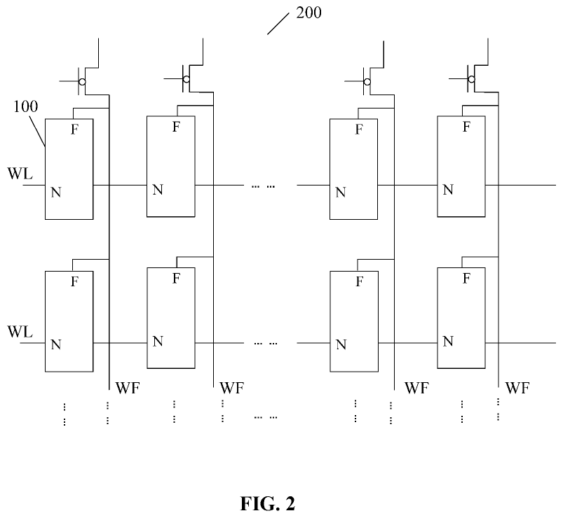

FIG. 2 is a schematic structural view of a conventional efuse memory. An efuse memory 200 includes a plurality of efuse memory cells 100 arranged in rows and columns. A gate terminal N of an NMOS (not shown) transistor of each of the plurality of efuse memory cells 100 is connected to a word line WL, and the word line WL is a signal line for controlling read operations. One terminal F of an electric fuse of each of the plurality of efuse memory cells 100 is connected to a bit line WF for write operations. It can be seen that in the conventional solutions, the read operations and the write operations are interrelated and inseparable.

In existing efuse memories, core devices are relatively small in size and large in current. Since an efuse is a one-time programming module, to overcome a reliability problem of a high programming voltage, the programming voltage can be reduced by limiting a cumulative programming time, so that the programming voltage is less than twice of a core voltage. However, considering that once there are multiple efuse memory cells in a same bit line, a leakage current of an ultra-low threshold voltage transistor (ULVT) may cause an efuse read operation to fail, so the conventional solutions usually adopt standard voltage transistors, rather than ultra-low threshold voltage transistors with smaller sizes, to form efuse memory cells. Further, when a core device with a standard voltage is used, its minimum power supply voltage cannot be lower than a normal circuit, which results in that a conventional efuse memory cell cannot be used in low-voltage Internet of Things (IoT) applications.

To solve the above technical problems, one embodiment of the present disclosure provides an efuse memory cell. The efuse memory cell has a write bit line terminal, a read bit line terminal, a read word line terminal, and a write word fine terminal. The efuse memory cell further includes an electric fuse having a first terminal and a second terminal, such that the first terminal of the electric fuse is connected to the write bit line terminal; a first control transistor having a first terminal, a second terminal, and a control terminal, such that the first terminal of the first control transistor is connected to the second terminal of the electric fuse, the second terminal of the first control transistor is connected to the read bit line terminal, and the control terminal of the first control transistor is connected to the read word line terminal; and a second control transistor having a first terminal, a second terminal and a control terminal, such that the first terminal of the second control transistor is connected to the second terminal of the electric fuse, the second terminal of the second control transistor is a ground terminal, and the control terminal of the second control transistor is connected to the write word line terminal.

Compared to the conventional solutions, since embodiments of the present disclosure use different control transistors (for example, the first control transistor and the second control transistor) to perform read and write operations, the read operations and the write operations can be separated. Further, because read and write operations are separated, a lower voltage can be used to perform the read operations, thereby reducing the voltage of the read operations, and reducing power consumption.

The above described objects, features and advantages of the present disclosure may become easier to be understood from the embodiments of the present disclosure described in detail below with reference to the accompanying drawings.

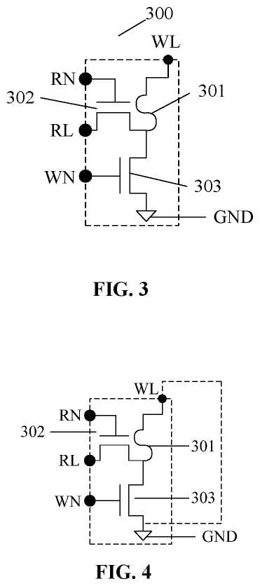

FIG. 3 is a schematic structural view of an efuse memory cell according to one embodiment of the present disclosure. An efuse memory cell 300 is adapted to perform read operations and write (also known as programming) operations.

In an alternative implementation, referring to FIG. 3, the efuse memory cell 300 has a write bit line terminal (illustrated as terminal WL), a read bit line terminal (illustrated as terminal RL), a read word line terminal (illustrated as terminal RN), and a write word line terminal (illustrated as terminal WN).

With continued reference to FIG. 3, the efuse memory cell 300 further includes an electric fuse 301, a first control transistor 302, and a second control transistor 303.

Alternatively, the electric fuse 301 has a first terminal and a second terminal, and the first terminal of the electric fuse 301 is connected to the write bit line terminal WL.

The first control transistor 302 has a first terminal, a second terminal, and a control terminal. The first terminal of the first control transistor 302 is connected to the second terminal of the electric fuse 301, the second terminal of the first control transistor 302 is connected to the read bit line terminal RL, and the control terminal of the first control transistor 302 is connected to the read word line terminal RN.

The second control transistor 303 has a first terminal, a second terminal, and a control terminal. The first terminal of the second control transistor 303 is connected to the second terminal of the electric fuse, the second terminal of the second control transistor 303 is a ground terminal (shown as terminal GND), and the control terminal of the second control transistor 303 is connected to the write word line terminal WN.

Those skilled in the art understand that a first terminal may be one of a source terminal and a drain terminal of a transistor, and a second terminal may be another one of the source terminal and the drain terminal of the transistor.

In one embodiment, the first control transistor 302 may be an Ultra-low Threshold Voltage Transistor (ULVT), and the second control transistor 303 may be an ULVT.

Those skilled in the art understand that in the conventional solutions, to perform a write operation on a conventional efuse memory cell, a higher voltage power supply is often required. For example, a Standard Threshold Voltage (SVT) voltage defined in a SVT library is used to supply power, or a High Threshold Voltage (HVT) voltage defined in an HVT library is used to supply power, or even an Ultra-High Threshold Voltage (UHVT for short) voltage defined in a UHVT library is used to supply power. Because a same transistor (as shown in FIG. 1) is used for read and write operations, a power supply voltage for read operations is often higher than an actual required voltage value for the conventional efuse memory cell.

However, in embodiments of the present disclosure, the first control transistor 302 is added to perform read operations, and the second control transistor 303 is used to perform write operations, so that the read and write operations are separated, and a voltage of the read operations can be reduced.

Alternatively, referring to FIG. 4, during a read operation, the write word line terminal WN connected to a write word line is closed, and the write bit line terminal WL is virtually grounded, and no current leakage occurs At a same time, the second control transistor 303 cannot be turned on. The read word line terminal RN connected to a read word line is turned on, and the read bit line terminal RL connected to a read bit line is powered on. When a read operation is performed, current flows through the first control transistor 302 and the electric fuse 301 and is virtually grounded to perform the read operation. Compared to the conventional solutions, a resistance can be reduced from about 100 ohms to less than about 10 ohms, which limits a value of a read current and a number of read operations is unlimited.

With continued reference to FIG. 3, during a write operation, the read word line terminal RN of the first control transistor 302 may be controlled to be turned off, and the write word line terminal WN of the second control transistor 303 may be controlled to be turned on. When the efuse memory cell is powered on through one terminal of the electric fuse 301, the electric fuse 301 and the second control transistor 303 form a loop, and then a fusing write operation to the electric fuse 301 can be performed.

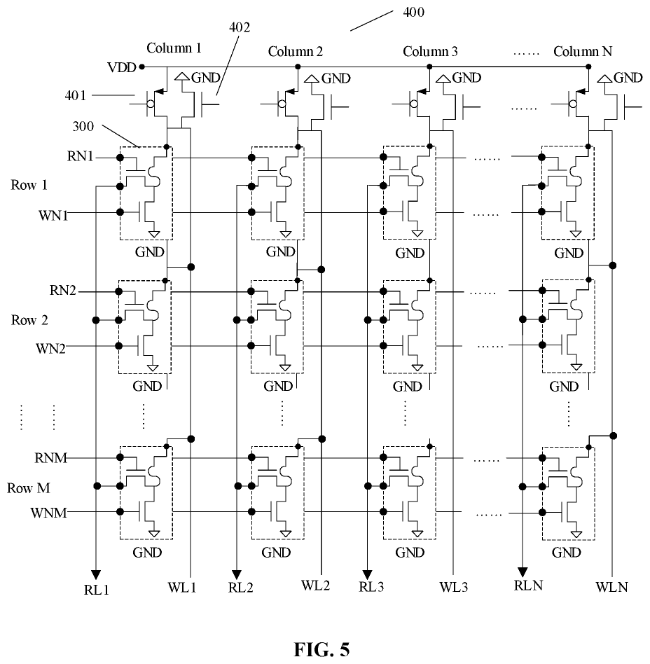

FIG. 5 is a schematic structural view of an efuse memory according to one embodiment of the present disclosure.

An efuse memory 400 may include: a plurality of read word lines for read operations, which extends in a horizontal direction; a plurality of write word lines for write operations, which extends in the horizontal direction; and a plurality of read bit lines for read operations and a plurality of write bit lines for write operations, which are arranged to intersect with the plurality of read word lines for read operations and the plurality of write word lines for write operations, and extend in a vertical direction.

In addition, the efuse memory 400 further includes a plurality of efuse memory cells 300 as shown in FIG. 3. The plurality of efuse memory cells 300 is arranged in M rows and N columns, where M and N are positive integers.

Referring to FIG. 5, respective terminals RN of efuse memory cells 300 in an i-th row (not shown) are connected to a same read word line for read operations, and respective terminals WN of the efuse memory cells 300 in the i-th row are connected to a same write word line for write operations, where the same read word line for read operations is an i-th read word line of the plurality of read word lines for read operations, and the same write word line for write operations is an i-th write word line of the plurality of write word lines for mite operations, 1≤i≤M, and i is a positive integer.

With continued reference to FIG. 5, respective terminals RL of efuse memory cells 300 in a j-th column (not shown) are connected to a same read bit line for read operations, and respective terminals WL of the efuse memory cells 300 in the j-th column is connected to a same write bit line for write operations, such that the same read bit line for read operations is a j-th read bit line of the plurality of read bit lines for read operations, and the same write bit line for write operations is a j-th write bit line of the plurality of write bit lines for write operations, 1≤j≤N, and j is a positive integer.

Further, the efuse memory 400 may further include a plurality of PMOS transistors 401 and a plurality of NMOS transistors 402. Each of the plurality of write bit lines may be connected to a first terminal of a PMOS transistor 401 of the plurality of PMOS transistors 401, and a second terminal of the PMOS transistor 401 of the plurality of PMOS transistors 401 is a power terminal. Each of the plurality of write bit lines may be connected to a first terminal of air NMOS transistor 402 of the plurality of NMOS transistors 402, and a second terminal of the NMOS transistor 402 of the plurality of NMOS transistors 402 is a ground terminal. The first terminal is one of a source terminal and a drain terminal, and the second terminal is another one of the source terminal and the drain terminal.

For a PMOS transistor 401 in the j-th column, a first terminal of the PMOS transistor 401 is connected to the j-th write bit line, and a second terminal is a power supply terminal. For an NMOS transistor in the j-th column, a first terminal is connected to the j-th write bit line, and a second terminal is a ground terminal. The first terminal is one of a source terminal and a drain terminal, and the second terminal is another one of the source terminal and the drain terminal.

In an alternative implementation, the efuse memory 400 may further include a plurality of sense amplifiers (not shown), and the plurality of read bit lines are connected to the plurality of sense amplifiers one-to-one, that is, each read bit line is connected to a corresponding sense amplifier.

In an alternative implementation, a write operation may be performed on the efuse memory 400 according to the following steps. Alternatively, when a write operation is performed on an efuse memory cell 300 to be written, a PMOS transistor 401 connected to the efuse memory cell 300 to be written can be controlled to be turned on, a write bit line connected to the efuse memory cell 300 to be written is powered on, and an NMOS transistor 402 connected to the efuse memory cell 300 to be written is turned off.

Correspondingly, a first control transistor 302 of the efuse memory cell 300 to be written can also be controlled to be turned off, and a write word line connected to the efuse memory cell 300 to be written is powered on, to blow an electric fuse 301 of the efuse memory cell 300 to be written to perform a write operation on the efuse memory cell 300 to be written.

For example, to perform a write operation on an efuse memory cell 300 located in the i-th row and the j-th column in the efuse memory 400, the following steps may be performed.

First, a PMOS transistor 401 connected to the efuse memory cell 300 in the i-th row and the i-th column is controlled to be turned on, the j-th write bit line connected to the efuse memory cell 300 is turned on, and an NMOS transistor 402 connected to the efuse memory cell 300 is turned off.

After that, a first control transistor 302 of the efuse memory cell 300 is controlled to be turned off, and the i-th write word line connected to the efuse memory cell 300 is powered on, to blow an electric fuse of the efuse memory cell 300 to perform a write operation on the efuse memory cell 300.

In an alternative implementation, a read operation on the efuse memory 400 may include the following steps.

When performing a read operation, an efuse memory cell 300 to be read is determined. After that, an NMOS transistor connected to the efuse memory cell 300 to be read is controlled to be turned on, a read bit line connected to the efuse memory cell 300 to be read is powered on, and a PMOS transistor 401 connected to the efuse memory cell 300 to be read is turned off.

Correspondingly, a second control transistor 303 of the efuse memory cell 300 to be read is also required to be turned off and a read word line connected to the efuse memory cell 300 to be read is powered on to perform a read operation on the efuse memory cell 300 to be read.

For example, a read operation on the efuse memory cell 300 located in the i-th row and the j-th column in the efuse memory 400 can be performed as follows.

The NMOS transistor 402 connected to the efuse memory cell 300 in the i-th row and the j-th column is controlled to be turned on, the j-th read bit line connected to the efuse memory cell 300 is powered on, and the PMOS transistor connected to the efuse memory cell is turned off.

Further, a second control transistor 303 of the efuse memory cell 300 needs to be turned off, and the i-th word read line connected to the efuse memory cell 300 is powered on to perform a read operation on the efuse memory cell 300.

The embodiments of the present disclosure add a control transistor to achieve separation of read and write operations of an efuse memory cell. Compared to the conventional solutions, which uses only a relatively large control transistor for read and write operations, the embodiments of the present disclosure can adopt a smaller size ULVT transistor to reduce a read current and save power. Further, despite an addition of one control transistor, a size of two ULVT transistors is still smaller than a SVT or HVT NMOS transistor used in the conventional solutions, so that a size of a memory cell and a memory array can be significantly reduced.

Compared to the conventional solutions, the technical solution of the embodiments of the present disclosure has the following beneficial effects.

One embodiment of the present disclosure provides an efuse memory cell. The efuse memory cell has a write bit line terminal, a read bit line terminal, a read word line terminal, and a write word line terminal. The efuse memory cell further includes: an electric fuse, having a first terminal and a second terminal, such that the first terminal of the electric fuse is connected to the write bit line terminal; a first control transistor, having a first terminal, a second terminal, and a control terminal, such that the first terminal of the first control transistor is connected to the second terminal of the electric fuse, the second terminal of the first control transistor is connected to the read bit line terminal, and the control terminal of the first control transistor is connected to the read word line terminal; and a second control transistor, having a first terminal, a second terminal, and a control terminal, such that the first terminal of the second control transistor is connected to the second terminal of the electric fuse, the second terminal of the second control transistor is a ground terminal, and the control terminal of the second control transistor is connected to the write word line terminal. Compared to the conventional solutions, since the embodiments of the present disclosure use different control transistors (for example, the first control transistor and the second control transistor) to perform read and write operations, the read operations and the write operations can be separated. Further, because read and write operations are separated, a lower voltage can be used to perform the read operations, thereby reducing a voltage of the read operations, and reducing power consumption.

Further, the first control transistor is an ultra-low threshold voltage transistor, and the second control transistor is an ultra-low threshold voltage transistor. Compared to a standard threshold voltage transistor used in the conventional solutions, the first control transistor and the second control transistor used in the embodiments of the present disclosure a two ultra-low threshold voltage transistors with smaller volume and lower voltage, which replace standard voltage threshold transistors or high voltage threshold transistors with larger volumes used in the conventional solutions, and can reduce volumes of efuse memory cells.

The embodiments disclosed herein are exemplary only. Other applications, advantages, alternations, modifications, or equivalents to the disclosed embodiments that are obvious to those skilled in the art are intended to be encompassed within the scope of the present disclosure.

What is claimed is:

1. An efuse memory cell, comprising:
a write bit line terminal;
a read bit fine terminal;
a read word line terminal;
a write word line terminal;
an electric fuse, having a first terminal and a second terminal, wherein the first terminal of the electric fuse is connected to the write bit line terminal;
a first control transistor, having a first terminal, a second terminal, and a control terminal, wherein the first terminal of the first control transistor is connected to the second terminal of the electric fuse, the second terminal of the first control transistor is connected to the read bit line terminal, and the control terminal of the first control transistor is connected to the read word line terminal; and
a second control transistor, having a first terminal, a second terminal, and a control terminal, wherein the first terminal of the second control transistor is connected to the second terminal of the electric fuse, the second terminal of the second control transistor is a ground terminal, and the control terminal of the second control transistor is connected to the write word line terminal.

2. The efuse memory cell according to claim 1, wherein:
the first control transistor is an ultra-low threshold voltage transistor, and the second control transistor is an ultra-low threshold voltage transistor.

3. An efuse memory, comprising:
a plurality of read word lines;
a plurality of write word lines;
a plurality of read bit lines;
a plurality of write bit lines; and
a plurality of efuse memory cells, arranged in M rows and N columns, and M and N are positive integers, wherein:
each of the plurality of efuse memory cells includes:
a write bit line terminal;
a read bit line terminal;
a read word line terminal;
a write word line terminal;
an electric fuse, having a first terminal and a second terminal, wherein the first terminal of the electric fuse is connected to the write bit line terminal;
a first control transistor, having a first terminal, a second terminal, and a control terminal, wherein the first terminal of the first control transistor is connected to the second terminal of the electric fuse, the second terminal of the first control transistor is connected to the read bit line terminal, and the control terminal of the first control transistor is connected to the read word line terminal; and
a second control transistor, having a first terminal, a second terminal, and a control terminal, wherein the first terminal of the second control transistor is connected to the second terminal of the electric fuse, the second terminal of the second control transistor is a ground terminal, and the control terminal of the second control transistor is connected to the write word line terminal;
the read word line terminal of each of the plurality of efuse memory cells in a same row is connected to a same read word line, and the write word line terminal of each of the plurality of efuse memory cells in the same row is connected to a same write word line, wherein the same read word line is one of the plurality of read word lines, and the same write word line is one of the plurality of write word lines; and
the read bit line terminal of each of the plurality of efuse memory cells in a same column is connected to a same read bit line, and the write bit line terminal of each of the plurality of efuse memory cells in the same column is connected to a same write bit line, wherein the same read bit line is one of the plurality of read bit lines, and the same write bit line is one of the plurality of write bit lines.

4. The efuse memory according to claim 3, wherein:
each write bit line of the plurality of write bit lines is connected to a first terminal of a PMOS transistor, and a second terminal of the PMOS transistor is a power terminal; and
each write bit line of the plurality of write bit lines is connected to a first terminal of an NMOS transistor, and a second terminal of the NMOS transistor is a ground terminal, wherein:
the first terminal of the PMOS transistor is one of a source terminal and a drain terminal, and the second terminal of the PMOS transistor is another one of the source terminal and the drain terminal; and
the first terminal of the NMOS transistor is one of another source terminal and another drain terminal, and the second terminal of the NMOS transistor is another one of the another source terminal and the another drain terminal.

5. The efuse memory according to claim 4, further comprising:
a plurality of sense amplifiers, one-to-one connecting to the plurality of read bit lines.

6. A write method, for writing the efuse memory according to claim 4, comprising:
controlling to turn on for a connection of a PMOS transistor connected to one of the plurality of efuse memory cells to be written; powering on one write bit line of the plurality of write bit lines connected to the one of the plurality of efuse memory cells to be written; and turning off for a disconnection of an NMOS transistor connected to the one of the plurality of efuse memory cells to be written; and
controlling to turn off for a disconnection of the first control transistor of the one of the plurality of efuse memory cells to be written; and powering on one write word line of the plurality of write word lines connected to the one of the plurality of efuse memory cells to be written to blow the electric fuse of the one of the plurality of efuse memory cells to be written, to perform a write operation on the one of the plurality of efuse memory cells to be written.

7. A read method, for writing the efuse memory according to claim 4, comprising:
controlling to turn on for a connection of an NMOS transistor connected to one of the plurality of efuse memory cells to be read; powering on one read bit line of the plurality of read bit lines connected to the one of the plurality of efuse memory cells to be read; and turning off for a disconnection of a PMOS transistor connected to the one of the plurality of efuse memory cells to be read; and
controlling to turn off for a disconnection of the second control transistor of the one of the plurality of efuse memory cells to be read; and powering on one read word line of the plurality of read word lines connected to the one of the plurality of efuse memory cells to be read, to perform a read operation on the one of the plurality of efuse memory cells to be read.
